(19) United States
(12) Patent Application Publication
(10) Pub. No.: US 2007/0115734 A1
(43) Pub. Date: May 24, 2007

(54) Method of operating an integrated circuit tester employing a float-to-ratio conversion with denominator limiting

(76) Inventor: S. Scott Schurr, Portland, OR (US)

Correspondence Address: SMITH-HILL AND BEDELL, P.C., 16100 NW CORNELL ROAD, SUITE 220, BEAVERTON, OR, 97006, US

(21) Appl. No.: 11/286,247

(22) Filed: Nov. 22, 2005

(51) Int. Cl. G11C 29/00

(52) U.S. Cl. 365/201

(57) ABSTRACT

A digital integrated circuit tester is prepared for testing a device having multiple time domains by specifying at least two cycle durations as literal times and selecting one of the cycle durations as a reference cycle duration. For each cycle duration other than the reference cycle duration, the literal time specified for that cycle duration is divided by the literal time specified for the reference cycle duration. The result of each division is converted into a ratio using a denominator limiting algorithm and a time domain of the tester is set in accordance with the ratio.

### BACKGROUND OF THE INVENTION

This invention relates to a method of operating an integrated circuit (IC) tester employing a float-to-ratio conversion with denominator limiting.

A typical digital semiconductor integrated circuit is composed of numerous functional blocks each characterized by a clock speed or frequency. A change in state of an input to a block may propagate through the block in a time period that is a multiple of the period of the clock speed that characterizes the block. The set of functional blocks that are characterized by a given clock speed is known as a time domain of the device. A complex integrated circuit device may have several time domains, and each time domain may be connected to pins at the exterior of the device for receiving input signals or supplying output signals.

A semiconductor integrated circuit tester that is to be used for testing units of an IC device having multiple time domains should have multiple time domains that can be associated respectively with the time domains of the device under test (DUT). Each time domain of the tester is connected to the pins of the corresponding time domain of the DUT and the test activities conducted at the pins of a given time domain all run together at the same speed. The test activities typically involve driving some pins to predetermined logic levels (high or low) at selected times during a test cycle and comparing voltage levels at other pins to predetermined thresholds at selected times during the test cycle.

A given time domain of an integrated circuit tester may change its operating speed during a test. In this event, the test activities performed at the associated DUT pins change speed together.

An important step in designing a test for an integrated circuit device is selection of the timing parameters that characterize the time domains of the tester interface. The tester may include a user interface that allows the user of the tester (who may be, for example, a circuit designer or a test engineer) to group together the tester pins on a time domain basis and to specify the cycle duration of each time domain.

It will be understood that cycle duration may be specified in terms of time (seconds) or frequency (1/seconds). Currently, it is conventional for the user to define test cycle duration in terms of time. Each time a different cycle duration is selected, the time domain runs at a different operating speed.

It has become a common practice to use phase locked loops in integrated circuits. This practice has affected both the device under test, in which a reference signal for a phase locked loop (PLL) might originate in one time domain and the output signal of the PLL might influence another time domain, and the tester, where the reference signal for a PLL might originate in one time domain and the output signal of the PLL might influence another time domain.

In a PLL, the frequency of the output signal is a rational multiple of the reference frequency. Accordingly, in many cases the ratio between cycle durations has become more critical to device behavior than the actual duration of those cycles. However, many users of testers are still accustomed to thinking in terms of cycle durations rather than ratios of cycle durations. It would be helpful to provide the user with a convenient way to bridge the gap from the time-based way of thinking to the ratio-based way of thinking.

Table I illustrates how cycle durations might typically be specified in connection with a test to be carried out using a digital integrated circuit tester. Column A indicates the actual cycle durations and column B indicates the corresponding frequencies. Column C indicates how a user might specify the cycle durations. Column C shows that the user may refer to the cycle duration E1 as 0.156 ns rather than 0.15625 ns, because users are accustomed to specifying no more than three or four significant digits and will omit the last few digits of a highly divided number that is specified to five or more significant digits.

TABLE I

| | A | | B | | C | | D |
|---|---|---|---|---|---|---|---|
| Time Domain A | | | | | | | |
| Cycle Duration A1 | 40 | ns | 25 | MHz | 40 | ns | 8:1 |
| Cycle Duration A2 | 20 | ns | 50 | MHz | 20 | ns | 4:1 |
| Time Domain B | | | | | | | |
| Cycle Duration B1 | 5 | ns | 200 | MHz | 5 | ns | 1:1 |
| Time Domain C | | | | | | | |
| Cycle Duration C1 | 1 | ns | 1 | GHz | 1 | ns | 1:5 |
| Time Domain D | | | | | | | |
| Cycle Duration D1 | 0.4 | ns | 2.5 | GHz | 0.4 | ns | 2:25 |
| Time Domain E | | | | | | | |
| Cycle Duration E1 | 0.15625 | ns | 6.4 | GHz | 0.156 | ns | 1:32 |

### SUMMARY OF THE INVENTION

According to a first aspect of the present invention there is provided a method of preparing a digital integrated circuit tester for testing a device having multiple time domains, comprising (a) specifying at least two cycle durations as literal times, (b) selecting one of the cycle durations as a reference cycle duration, (c) for each cycle duration other than the reference cycle duration, dividing the literal time specified in step (a) for that cycle duration by the literal time specified in step (a) for the reference cycle duration, (d) converting the result of each division into a ratio using a denominator limiting algorithm, and (e) setting a time domain of the tester in accordance with the ratio obtained from step (d).

According to a second aspect of the present invention there is provided an integrated circuit tester for testing a device having multiple time domains, wherein the tester includes an interface by which a user may specify at least two cycle durations as literal times and the tester includes a computer programmed to perform the following steps: (a) select one of the cycle durations as a reference cycle duration, (b) for each cycle duration other than the reference cycle duration, divide the literal time specified in step (b) for that cycle duration by the literal time specified in step (a) for the reference cycle duration, and (c) convert the result of each division into a ratio using a denominator limiting algorithm.

According to a third aspect of the present invention there is provided a computer readable medium having recorded thereon a program that, when loaded into a computer having an interface by which a user may specify at least floating point numbers, causes the computer to perform the following steps: (a) select one of the numbers as a reference number, (b) for each specified number other than the reference number, divide that number by the reference number selected in step (a), and (c) convert the result of each division into a ratio using a denominator limiting algorithm.

### BRIEF DESCRIPTION OF THE DRAWINGS

For a better understanding of the invention, and to show how the same may be carried into effect, reference will now be made, by way of example, to the accompanying drawings, in which:

FIG. 1 illustrates schematically part of a semiconductor integrated circuit tester that can be operated in accordance with a method embodying the present invention,

FIG. 2 is a flow diagram illustrating a program flow in a float-to-ratio conversion program, and

FIG. 3 illustrates a detail of the program shown in FIG. 2.

### DETAILED DESCRIPTION

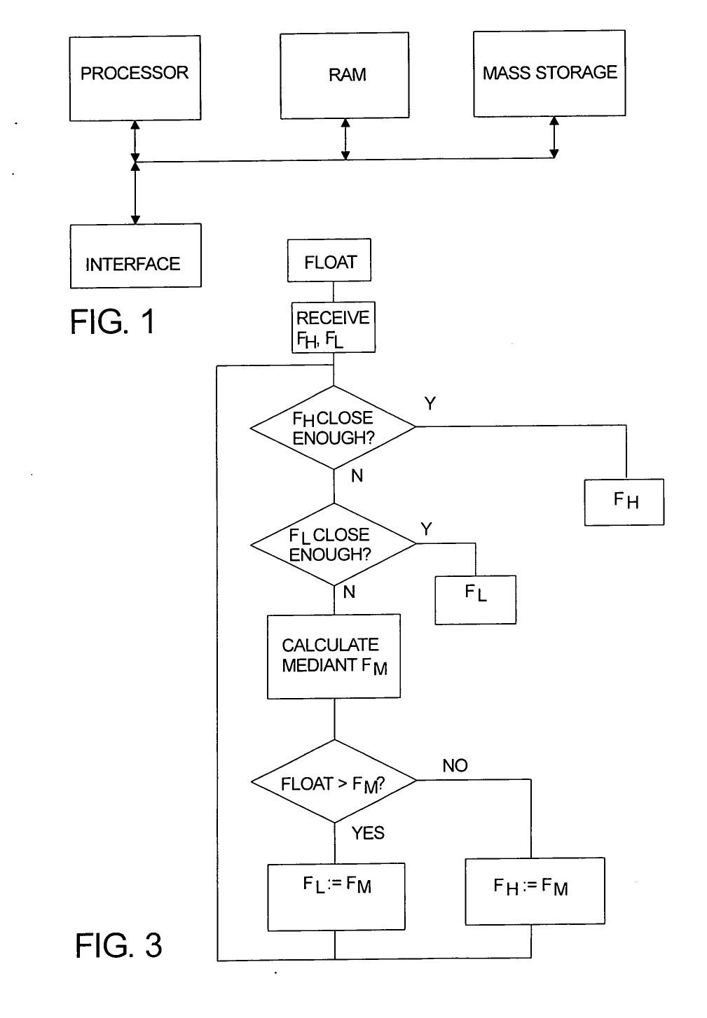

A typical semiconductor integrated circuit tester includes multiple test instruments, such as logic test instruments, analog waveform generators, digital capture ports, waveform digitizers, etc. Some instruments of the tester are ratio based instruments, in which cycle duration is displayed to the user interface as a ratio relative to a master cycle duration, and other instruments are non-ratio based instruments, in which the cycle duration is displayed to the user interface as a floating-point number specifying a time in seconds. Operation of the tester is coordinated using a computer, which may include the functional blocks shown in FIG. 1.

The computer shown in FIG. 1 includes a processor, random access memory, mass storage and a user interface (display monitor and input devices, such as a keyboard and mouse). The user interface allows the user of the tester to define test parameters, including grouping of tester channels into time domains and specifying cycle duration ratios.

A user who wishes to define a test will enter cycle durations using the user interface and will then invoke a conversion program. The processor retrieves the conversion program from the mass storage and runs the program.

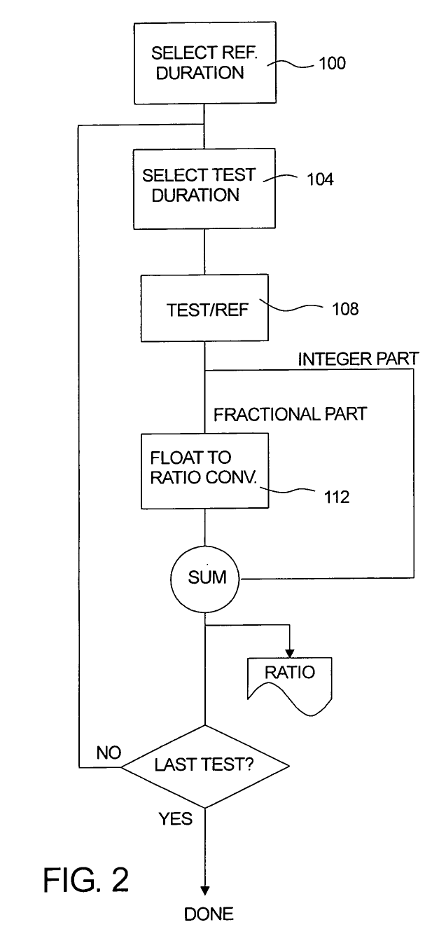

The conversion program may be written as a batch file. The program is illustrated schematically in FIGS. 2 and 3.

Referring to FIG. 2, in step 100 the conversion program selects a reference cycle duration. In one practical implementation of the invention, the reference cycle duration is the highest common factor of the cycle durations of the non-ratio based instruments. In other implementations, the reference cycle duration may be selected on a different basis.

In step 104, the program selects one of the other cycle durations as a test value. Let us assume that the program has selected the cycle duration of time domain B1 (5 ns) as the reference cycle duration and has selected the shortest cycle duration, i.e. the cycle duration of time domain E1, as the test value.

In step 108, the program divides the test value by the reference value. The result of the division is a floating point number that has an integer part and a fractional part. In the case of the example, the result is 0.0312. Thus, the integer part is zero and the fractional part is 0.0312.

The next step is to convert the floating point number 0.0312 to a ratio of integers. One conventional technique for converting a floating point number to a ratio involves use of continued fractions. However, use of continued fractions is subject to disadvantage because the procedure may skip intermediate, but valid, denominators. For example, a continued fraction calculation might give the ratio 39:1250 as the ratio corresponding to 0.0312, but it will be shown below that a ratio having a much smaller denominator should be acceptable.

The Farey series F_{N} is the series containing all fractions between 0 and 1 whose denominators do not exceed N, arranged in order of magnitude.

A property of the Farey series is that each member of a Farey series is the mediant fraction of its neighbors. For example, three consecutive members of the series F₆ are ⅙, ⅕ and ¼, and the mediant fraction of ⅙ and ¼ is ⅕. And for two consecutive members of the Farey series F_{N1}, the mediant fraction of these members is a member of a higher order Farey series F_{N2}, and the Farey series F_{N2} is the lowest order Farey series having a member that is intermediate in magnitude between two consecutive members of the series F_{N1}. For example, two consecutive members of the series F₆ are ⅙ and ⅕; the mediant fraction of ⅙ and ⅕ is 2/11 and the Farey series F₁₁ is the lowest order Farey series having a member that is between ⅙ and ⅕.

The conversion program identifies a fraction that is an acceptably close approximation to 0.0312 by starting with the Farey series F₁₁ containing the members 0/1 and 1/1. 0/1 differs too much from 0.0312 and in any event zero is an unacceptable solution so the program generates a value of the next higher order Farey series by calculating the mediant fraction of 0/1 and 1/1. The conversion program thus provides the fraction ½, which is a member of the Farey series F₂. The fraction ½ is not acceptable because it differs too much from 0.0312 so the program calculates the mediant fraction of 0/1 and ½ and obtains ⅓. The fraction ⅓ is also unacceptable. The process therefore continues and ultimately the program calculates the fraction 1/32, which is equal to 0.15625. The value 0.15625 ns should be acceptable since it is equal to the cycle duration E1, to the precision specified for that duration.

Finally, the program adds the ratio returned by step 112 to the integer part of the floating point number returned by step 108 and the program displays the resulting rational fraction ( 1/32 in the case of this example) on the user interface.

In the case of cycle duration D1, the conversion program calculates the floating point equivalent of the ratio 0.4/5, which is 0.08. In the manner described above, the conversion program displays the ratio 2:25.

When the program has calculated all the ratios, the user sets the time domains for the tester in accordance with the ratios displayed by the interface.

In this manner, the program effects a float-to-ratio conversion in a manner that returns the smallest denominator fraction, in that the next fraction that is selected in each iteration of the selection cycle is always the smallest denominator fraction that is intermediate in value between the two previous candidates.

FIG. 3 illustrates flow of a simple program that will perform the float-to-ratio conversion. The initial values of the high and low fractions (F_{H} and F_{L}) are 1/1 and 0/1, and in each iteration, depending on whether the floating point number is greater than the mediant fraction F_{M} of F_{H} and F_{L}, the value of F_{M} is assigned to the variable F_{H} or F_{L}.

It will be appreciated that the invention is not restricted to the particular procedure described above for identifying a fraction that is acceptably close to the reference value and has an acceptably small denominator. For example, assuming that the maximum denominator is 8, the conversion program could rank the members of the Farey series F₈ in order of magnitude as numbers 1-22. The program tests the input value (0.62, for example) against member 12 (½) and determines whether the input is larger or smaller. The program determines that 0.62 is not close enough to ½ and is larger than ½ so the program now test the input against number 12 (¾), dividing the interval between member 12 and member 22 in half. 0.62 is smaller than ¾ but is still not close enough, and the program divides the interval between member 12 and member 17 in half and tests the input against member 14 (⅝). ⅝ is quite close to 0.62 and is therefore acceptable.

Naturally, the program could be designed to use a brute force approach and start at member 1 and work its way through towards member 22.

It will be appreciated that the invention is not restricted to the particular embodiment that has been described, and that variations may be made therein without departing from the scope of the invention as defined in the appended claims and equivalents thereof. For example, although in the current practical implementation of the invention the user sets the time domains of the tester through the tester's user interface employing the ratios returned by the method, in a development the program could automatically set the time domains without requiring user interaction. Unless the context indicates otherwise, a reference in a claim to the number of instances of an element, be it a reference to one instance or more than one instance, requires at least the stated number of instances of the element but is not intended to exclude from the scope of the claim a structure or method having more instances of that element than stated. If the word “comprises” or “includes,” or a derivative of either of these words is used in this specification, including the claims, it is used in an inclusive, not exclusive or exhaustive, sense. Thus, for example, a statement that a component comprises first and second elements is not intended to exclude the possibility of the component including one or more additional elements.

1. A method of preparing a digital integrated circuit tester for testing a device having multiple time domains, comprising:
(a) specifying at least two cycle durations as literal times,
(b) selecting one of the cycle durations as a reference cycle duration,
(c) for each cycle duration other than the reference cycle duration, dividing the literal time specified in step (a) for that cycle duration by the literal time specified in step (a) for the reference cycle duration,
(d) converting the result of each division into a ratio using a denominator limiting algorithm, and
(e) setting a time domain of the tester in accordance with the ratio obtained from step (d).

2. A method according to claim 1, wherein step (d) comprises:
comparing the result of a division to two consecutive members of a Farey series and determining whether either member is an acceptably close approximation of said result and, if not,
calculating the mediant fraction of said two consecutive members and determining whether said mediant fraction is an acceptably close approximation of said result.

3. An integrated circuit tester for testing a device having multiple time domains, wherein the tester includes an interface by which a user may specify at least two cycle durations as literal times and the tester includes a computer programmed to perform the following steps:
(a) select one of the cycle durations as a reference cycle duration,
(b) for each cycle duration other than the reference cycle duration, divide the literal time specified in step (b) for that cycle duration by the literal time specified in step (a) for the reference cycle duration, and
(c) convert the result of each division into a ratio using a denominator limiting algorithm.

4. An integrated circuit tester according to claim 3, wherein the computer is programmed to set a time domain of the tester in accordance with the ratio obtained from step (c).

5. An integrated circuit tester according to claim 3, wherein step (c) comprises:
comparing the result of a division to two consecutive members of a Farey series and determining whether either member is an acceptably close approximation of said result and, if not,
calculating the mediant fraction of said two consecutive members and determining whether said mediant fraction is an acceptably close approximation of said result.

6. A computer readable medium having recorded thereon a program that, when loaded into a computer having an interface by which a user may specify at least floating point numbers, causes the computer to perform the following steps:
(a) select one of the numbers as a reference number,
(b) for each specified number other than the reference number, divide that number by the reference number selected in step (a), and
(c) convert the result of each division into a ratio using a denominator limiting algorithm.

7. A computer readable medium according to claim 7, wherein step (c) comprises:
comparing the result of a division to two consecutive members of a Farey series and determining whether either member is an acceptably close approximation of said result and, if not,
calculating the mediant fraction of said two consecutive members and determining whether said mediant fraction is an acceptably close approximation of said result.
